(19) United States
(12) Patent Application Publication
(10) Pub. No.: US 2013/0078571 A1
(43) Pub. Date: Mar. 28, 2013

(54) PHOTORESIST COMPOSITION, METHOD FOR PRODUCING PHOTORESIST COMPOSITION, AND METHOD FOR FORMING RESIST PATTERN

(71) Applicant: JSR CORPORATION, Tokyo (JP)

(72) Inventors: Ryuichi SERIZAWA, Tokyo (JP); Yusuke ASANO, Tokyo (JP)

(73) Assignee: JSR CORPORATION, Tokyo (JP)

(21) Appl. No.: 13/628,115

(22) Filed: Sep. 27, 2012

(30) Foreign Application Priority Data
Sep. 28, 2011 (JP) 2011-213093
Aug. 8, 2012 (JP) 2012-176397

(51) Int. Cl. G03F 7/004; G03F 7/20

(52) U.S. Cl. 430/270.1; 430/325

(57) ABSTRACT

A photoresist composition includes a first polymer, a second polymer and a third polymer. The first polymer has a fluorine atom and a first structural unit that includes a hydrophilic group. The second polymer has a fluorine atom a second structural unit that includes an alkali-dissociable group. The third polymer has an acid-dissociable group. The first polymer, the second polymer and the third polymer are different with one another. It is preferred that the first structural unit is represented by a following formula, and the second structural unit is represented by a following formula (2).

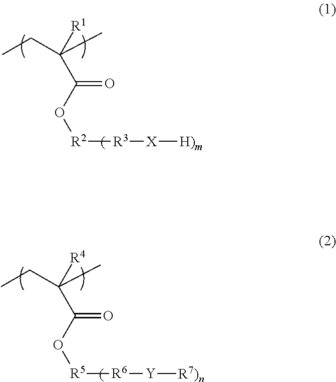

### CROSS-REFERENCE TO RELATED APPLICATIONS

The present application claims priority under 35 U.S.C. §119 to Japanese Patent Application No. 2011-213093, filed Sep. 28, 2011 and to Japanese Patent Application No. 2012-176397, filed Aug. 8, 2012. The contents of these applications are incorporated herein by reference in their entirety.

### BACKGROUND OF THE INVENTION

1. Field of the Invention

The present invention relates to a photoresist composition and a method for producing a photoresist composition, and a method for forming a resist pattern.

2. Discussion of the Background

Miniaturization of various types of electronic device structures such as semiconductor devices and liquid crystal devices has been accompanied by demands for miniaturization of resist patterns in lithography processes. Although fine resist patterns having a line width of about 90 nm can be formed using, for example, an ArF excimer laser at present, finer pattern formation is required in the future.

Conventionally, in such pattern formation, a chemically amplified type resist composition has been extensively employed. The chemically amplified type resist composition contains an acid generating component that generates an acid upon exposure, and a resin component whose solubility in developer solutions varies by the action of this acid (see Japanese Unexamined Patent Application, Publication No. S59-45439), whereby a pattern can be formed using the difference of rates of dissolution between a light-exposed site and a light-unexposed site.

On the other hand, it is reported that high resolving abilities can be attained according to liquid immersion lithography, even if a light source of the same exposure wavelength is employed, similarly to the case in which a light source of a shorter wavelength is employed in conventional resist pattern formation. Thus, the liquid immersion lithography has drawn attention as a technique that achieves high resolution in manufacturing semiconductor elements which require a large amount of investment in equipment while suppressing an increase in costs. As a photoresist composition suited for the liquid immersion lithography, in attempts to be capable of inhibiting elution of an acid generator and the like from a resist film to a liquid for liquid immersion lithography, and improving water break of the resist film, and the like, a photoresist composition was proposed which contains a fluorine atom-containing polymer that is highly hydrophobic (see PCT International Publication No. 2007/116664).

### SUMMARY OF THE INVENTION

According to one aspect of the present invention, a photoresist composition includes a first polymer, a second polymer and a third polymer. The first polymer has a fluorine atom and a first structural unit that includes a hydrophilic group. The second polymer has a fluorine atom a second structural unit that includes an alkali-dissociable group. The third polymer has an acid-dissociable group. The first polymer, the second polymer and the third polymer are different with one another.

According to another aspect of the present invention, a method for forming a resist pattern includes providing the photoresist composition on a substrate to form a resist film. The resist film is exposed with liquid immersion lithography. The exposed resist film is developed.

According to further aspect of the present invention, a method for producing a photoresist composition includes mixing a first polymer, a second polymer and a third polymer. The first polymer has a fluorine atom and a first structural unit that includes a hydrophilic group. The second polymer has a fluorine atom and a second structural unit that includes an alkali-dissociable group. The third polymer has an acid-dissociable group.

### DESCRIPTION OF THE EMBODIMENTS

According to one aspect of the embodiment of the present invention made for solving the aforementioned problems, a photoresist composition includes:
(A) a fluorine atom-containing polymer having a structural unit (I) that includes a hydrophilic group (hereinafter, may be also referred to as “polymer (A)”);
(B) a fluorine atom-containing polymer having a structural unit (II) that includes an alkali-dissociable group (hereinafter, may be also referred to as “polymer (B)”); and
(C) a polymer having an acid-dissociable group (hereinafter, may be also referred to as “polymer (C)”),
the polymer (A), the polymer (B) and the polymer (C) being different with one another. Here, the polymer (A), the polymer (B) and the polymer (C) are referred to above as the first polymer, the second polymer and the third polymer, respectively.

The photoresist composition contains the polymer (A), the polymer (B) and the polymer (C). Since the photoresist composition contains the polymer (A) and the polymer (B) that are a fluorine atom-containing polymer, hydrophobicity can be sufficiently secured during liquid immersion lithography. In addition, since the polymer (B) has a structural unit (II) that includes an alkali-dissociable group in the photoresist composition, an affinity with a developer solution can be improved during alkali development, and thus development defects can be suppressed. Furthermore, since the polymer (A) has a structural unit (I) that includes a hydrophilic group, it is assumed that a higher affinity with other components having a low amount of fluorine atoms can be attained. As a result, the photoresist composition enables the polymer (B) to be locally distributed to an area closer to the top surface of the resist film; therefore, the effect of suppressing development defects can be further improved. It is to be noted that preferred specific examples of the hydrophilic group as referred to herein include a carboxy group, a hydroxyl group, an active methylene group, an active methine group and a fluorinated sulfoneamide group, and a carboxy group, an active methylene group and an active methine group.

It is preferred that the structural unit (I) be represented by the following formula (1), and the structural unit (II) be represented by the following formula (2).

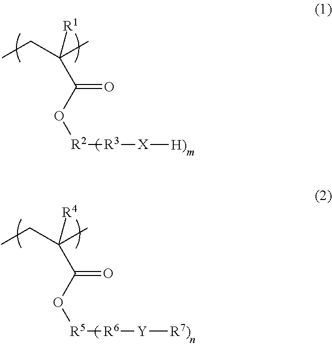

In the formula (1), R¹ represents a hydrogen atom, a fluorine atom, a methyl group or a trifluoromethyl group; R² represents a single bond or a hydrocarbon group having a valency of (m+1) and having 1 to 20 carbon atoms; R³ represents a single bond, a bivalent hydrocarbon group having 1 to 20 carbon atoms or a bivalent heterocyclic group having 4 to 20 carbon atoms; X represents a single bond, —CO—O—* or —O—, “*” denotes a site bound to a hydrogen atom; m is an integer of 1 to 3, wherein provided that m is 2 or greater, a plurality of R³s and Xs may be each the same or different, and a part or all of hydrogen atoms that the hydrocarbon group represented by the R² and R³ has are unsubstituted or optionally substituted.

In the formula (2), R⁴ represents a hydrogen atom, a fluorine atom, a methyl group or a trifluoromethyl group; R⁵ represents a hydrocarbon group having a valency of (n+1) and having 1 to 20 carbon atoms; R⁶ represents a single bond, a bivalent hydrocarbon group having 1 to 20 carbon atoms or a bivalent heterocyclic group having 4 to 20 carbon atoms; R⁷ represents a monovalent hydrocarbon group having 1 to 20 carbon atoms; Y represents —CO—O—* or —O—CO—*, “*” denotes a site bound to R⁷; n is an integer of 1 to 3, wherein provided that n is 2 or greater, a plurality of R⁶s, R⁷s and Ys may be each the same or different, and a part or all of hydrogen atoms that the hydrocarbon group represented by the R⁵, R⁶ and R⁷ has are unsubstituted or optionally substituted.

Due to the structural unit (I) and the structural unit (II) having the specified structure, the photoresist composition can further suppress generation of development defects.

A mass ratio of the polymer (A) to the polymer (B) is preferably no less than 0.2 and no greater than 2.0. When the photoresist composition contain the polymer (A) and the polymer (B) at the specified mass ratio, the effect of suppressing generation of development defects can be further improved.

The proportion of the polymer (C) contained with respect to the total of the polymers is preferably no less than 50% by mass. When the proportion of the polymer (C) contained falls within the specified range, the photoresist composition can further suppress generation of development defects, and enables superior sensitivity to be attained and a favorable resist pattern to be formed.

In the photoresist composition, the amount of the polymer (A) with respect to 100 parts by mass of the polymer (C) is preferably no less than 0.1 parts by mass and no greater than 10 parts by mass. When the proportion of the polymer (C) and the polymer (A) falls within the specified range, the photoresist composition can further suppress generation of development defects, and enables superior sensitivity to be attained and a favorable resist pattern to be formed.

According to another aspect, the method for forming a resist pattern of the embodiment of the present invention includes the steps of:
(1) forming a resist film on a substrate using the photoresist composition of the embodiment of the present invention;
(2) exposing the resist film with liquid immersion lithography; and
(3) developing the exposed resist film.

According to the method for forming a resist pattern, generation of development defects is suppressed, and thus a favorable resist pattern can be formed.

According to still another aspect, the method for producing a photoresist composition of the embodiment of the present invention includes a step of mixing:
(A) a fluorine atom-containing polymer having a structural unit (I) that includes a hydrophilic group;
(B) a fluorine atom-containing polymer having a structural unit (II) that includes an alkali-dissociable group; and
(C) a polymer having an acid-dissociable group.

Due to including the step of mixing the polymer (A), the polymer (B) and the polymer (C) in the method for producing a photoresist composition, while hydrophobicity can be sufficiently secured during liquid immersion lithography, an affinity with an alkaline developer can be improved in a development step according to the method for producing a photoresist composition; therefore, a photoresist composition capable of suppressing generation of development defects can be produced.

It is preferred that the structural unit (I) be represented by the following formula (1), and the structural unit (II) be represented by the following formula (2).

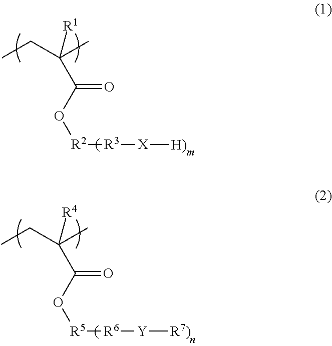

In the formula (1), R¹ represents a hydrogen atom, a fluorine atom, a methyl group or a trifluoromethyl group; R² represents a single bond or a hydrocarbon group having a valency of (m+1) and having 1 to 20 carbon atoms; R³ represents a single bond, a bivalent hydrocarbon group having 1 to 20 carbon atoms or a bivalent heterocyclic group having 4 to 20 carbon atoms; X represents a single bond, —CO—O—* or —O—, “*” denotes a site bound to a hydrogen atom; m is an integer of 1 to 3, wherein provided that m is 2 or greater, a plurality of R³s and Xs may be each the same or different, and a part or all of hydrogen atoms that the hydrocarbon group represented by the R² and R³ has are unsubstituted or optionally substituted.

In the formula (2), R⁴ represents a hydrogen atom, a fluorine atom, a methyl group or a trifluoromethyl group; R⁵ represents a hydrocarbon group having a valency of (n+1) and having 1 to 20 carbon atoms; R⁶ represents a single bond, a bivalent hydrocarbon group having 1 to 20 carbon atoms or a bivalent heterocyclic group having 4 to 20 carbon atoms; R⁷ represents a monovalent hydrocarbon group having 1 to 20 carbon atoms; Y represents —CO—O—* or —O—CO—*, “*” denotes a site bound to R⁷; and n is an integer of 1 to 3, wherein provided that n is 2 or greater, a plurality of R⁶s, R⁷s and Ys may be each the same or different, and a part or all of hydrogen atoms that the hydrocarbon group represented by R⁵, R⁶ and R⁷ has are unsubstituted or optionally substituted.

Due to the structural unit (I) and the structural unit (II) having the specified structure, a photoresist composition capable of further suppressing generation of development defects can be produced according to the method for producing a photoresist composition.

The mass ratio of the polymer (A) to the polymer (B) is preferably no less than 0.2 and no greater than 2.0. According to the method for forming a photoresist composition, due to containing the polymer (A) and the polymer (B) at the specified mass ratio, a photoresist composition capable of further improving the effect of suppressing generation of development defects can be produced.

The proportion of the polymer (C) contained with respect to the total of the polymers is preferably no less than 50% by mass. According to the method for producing a photoresist composition, when the proportion of the polymer (C) contained falls within the specified range, a photoresist composition can be produced which can further suppress generation of development defects, and enables superior sensitivity to be attained and a favorable resist pattern to be formed.

In the method for producing a photoresist composition, the amount of the polymer (A) with respect to 100 parts by mass of the polymer (C) is preferably no less than 0.1 parts by mass and no greater than 10 parts by mass. According to the method for producing a photoresist composition, when the proportion of the polymer (C) and the polymer (A) falls within the specified range, a photoresist composition can be produced which can further suppress generation of development defects, and enables superior sensitivity to be attained and a favorable resist pattern to be formed.

When a photoresist composition containing the fluorine atom-containing polymer that is highly hydrophobic is used, elimination of development residues on the resist surface in development may be insufficient due to inferior surface wettability of a developer solution and/or a rinse liquid, whereby development defects may be generated. According to the photoresist composition of the embodiment of the present invention, a resist film can be formed with an affinity with a developer solution increased in a development while hydrophobicity can be secured during liquid immersion lithography, whereby generation of development defects can be suppressed. In addition, according to the method for producing a photoresist composition of the embodiment of the present invention, the photoresist composition capable of suppressing generation of development defects can be produced.

The embodiments will now be described in detail.

### <Photoresist Composition>

The photoresist composition contains as essential components the polymer (A), the polymer (B) and the polymer (C). In addition, the photoresist composition preferably contains (D) an acid generator, (E) an acid diffusion control agent and/or (F) a solvent, and may also contain other optional component as long as the effects of the present invention are not impaired. Hereinafter, each component will be explained in detail.

### <(A) Polymer>

The polymer (A) is a fluorine atom-containing polymer having a structural unit (I) that includes a hydrophilic group. In the photoresist composition, since the polymer (A) has a structural unit (I) that includes a hydrophilic group, an affinity with other components having a low content of fluorine atoms such as the polymer (C) described later is enhanced. As a result, the photoresist composition can form a resist film having a structure in which a layer containing the polymer (A) as a principal component is laminated on a layer containing as a principal component a component having a low content of fluorine atoms such as the polymer (C), and further thereon a layer containing as a principal component the polymer (B) having an alkali-dissociable group described later is laminated. Accordingly, by enabling the polymer (B) to be locally distributed to an area closer to the top surface of the resist film, the resist film formed from the photoresist composition has a high affinity with an alkaline developer, and thus generation of development defects can be suppressed. In addition to the structural unit (I), the polymer (A) may have a structural unit (II) that includes an alkali-dissociable group described in detail in explanation of the polymer (B), as well as a structural unit (III) that includes an acid-dissociable group and/or a structural unit (IV) containing a fluorine atom described in detail in explanation of the polymer (C), etc. It is to be noted that the polymer (A) may have either one type of each structural unit alone, or two or more types thereof. Hereinafter, each structural unit will be described in detail.

### [Structural Unit (I)]

The structural unit (I) includes a hydrophilic group. The hydrophilic group is preferably a carboxy group and a hydroxyl group. Also, the structural unit (I) is not particularly limited as long as it is a structural unit that includes a hydrophilic group, and is preferably a structural unit represented by the above formula (1).

In the above formula (1), R¹ represents a hydrogen atom, a fluorine atom, a methyl group or a trifluoromethyl group; R² represents a single bond or a hydrocarbon group having a valency of (m+1) and having 1 to 20 carbon atoms; R³ represents a single bond or a bivalent hydrocarbon group having 1 to 20 carbon atoms; X represents a single bond, —CO—O—* or —O—, “*” denotes a site bound to a hydrogen atom; m is an integer of 1 to 3, wherein provided that m is 2 or greater, a plurality of R³s and Xs may be each the same or different, and a part or all of hydrogen atoms that the hydrocarbon group represented by the R² and R³ has are unsubstituted or optionally substituted.

Examples of the hydrocarbon group having a valency of (m+1) and having 1 to 20 carbon atoms represented by R² include linear or branched chain hydrocarbon groups having a valency of (m+1) and having 1 to 20 carbon atoms, alicyclic hydrocarbon groups having a valency of (m+1) and having 4 to 20 carbon atoms, and the like.

Examples of the linear or branched chain hydrocarbon group having a valency of (m+1) and having 1 to 20 carbon atoms include groups derived by removing (m+1) hydrogen atoms from an alkane such as methane, ethane, propane, butane, pentane, hexane, octane, decane or dodecane, and the like.

Examples of the alicyclic hydrocarbon group having a valency of (m+1) and having 4 to 20 carbon atoms include groups derived by removing (m+1) hydrogen atoms from a cycloalkane such as cyclobutane, cyclopentane, cyclohexane, cyclooctane, cyclodecane, cyclododecane, norbornane or adamantane, and the like.

The R² preferably represents a single bond, or a linear or branched hydrocarbon group.

Examples of the bivalent hydrocarbon group having 1 to 20 carbon atoms represented by the R³ include bivalent linear or branched hydrocarbon groups having 1 to 20 carbon atoms, bivalent alicyclic hydrocarbon groups having 4 to 20 carbon atoms, and the like.

Examples of the bivalent linear or branched hydrocarbon group having 1 to 20 carbon atoms include a methylene group, an ethanediyl group, a propanediyl group, a butanediyl group, a pentanediyl group, a hexanediyl group, a decanediyl group, a dodecanediyl group, and the like.

Examples of the bivalent alicyclic hydrocarbon group having 4 to 20 carbon atoms include a cyclobutanediyl group, a cyclopentanediyl group, a cyclohexanediyl group, a cyclodecanediyl group, a cyclododecanediyl group, a norbornylene group, an adamantylene group, and the like.

The R³ preferably represents a single bond, or a linear or branched hydrocarbon group.

The m is preferably 1 or 2, and more preferably 1.

The structural unit (I) in which the X, R² and R³ represent a single bond, and the structural unit (I) in which the X represents —CO—O— or —O—, and R² and/or R³ represents a linear or branched hydrocarbon group are preferred.

The structural unit (I) is exemplified by structural units represented by represented by the following formulae, and the like.

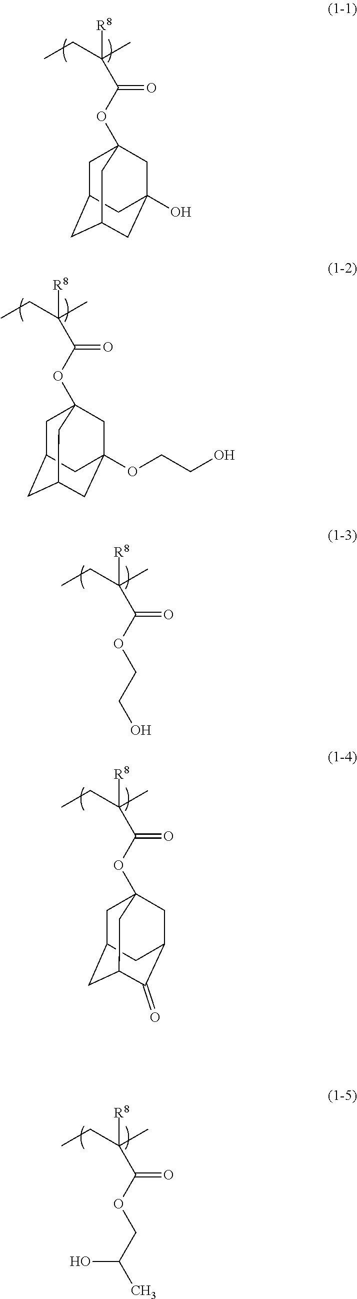

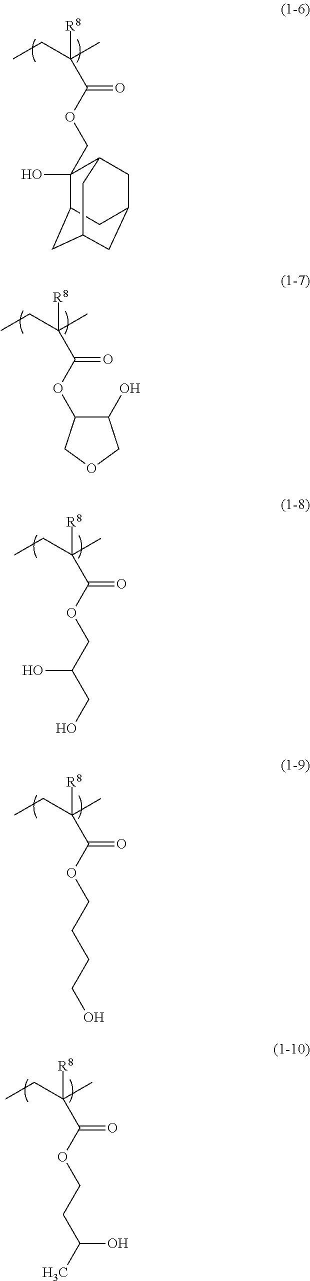

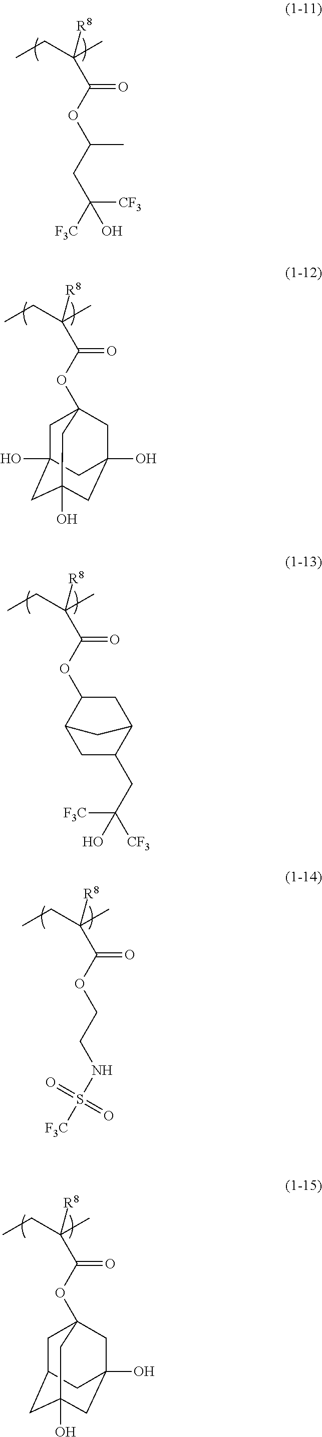

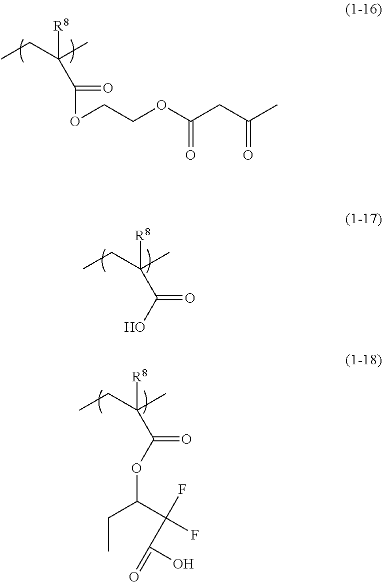

In the above formulae, R⁸ represents a hydrogen atom, a fluorine atom, a methyl group or a trifluoromethyl group.

Of these, structural units represented by the above formulae (1-1), (1-3), (1-5), (1-6), (1-8) to (1-13), (1-15), (1-17) and (1-18) that are the structural unit represented by the above formula (1) are preferred, and structural units represented by the above formulae (1-17) and (1-18) are more preferred.

Examples of the monomer that gives the structural unit (I) include monomers represented by the following formulae, and the like.

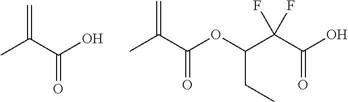

In the polymer (A), the proportion of the structural unit (I) contained is preferably no less than 5 mol % and no greater than 100 mol %, more preferably no less than 10 mol and no greater than 90 mol %, and still more preferably no less than 20 mol % and no greater than 80 mol %. Due to the proportion of the structural unit (I) falling within the above range, the photoresist composition can further suppress the generation of development defects.

### [Structural Unit (II)]

The polymer (A) may have a structural unit (II) that includes an alkali-dissociable group. When the polymer (A) further has the structural unit (II), the resist film formed from the photoresist composition can have can have an even superior affinity with the alkaline developer; therefore, generation of development defects can be further suppressed. It is to be noted that with respect to the structural unit (II), details of the structural unit (II) in the polymer (B) described later may be adopted.

The proportion of the structural unit (II) contained in the polymer (A) is preferably no greater than 90 mol %, and more preferably no greater than 80 mol %. Due to the proportion of the structural unit (II) falling within the above range, the photoresist composition can further suppress the generation of development defects.

### [Structural Unit (III)]

The polymer (A) may have a structural unit (III) that includes an acid-dissociable group. When the polymer (A) further has the structural unit (III), the photoresist composition can have improved sensitivity. It is to be noted that with respect to the structural unit (III), details of the structural unit (III) in the polymer (C) described later may be adopted.

The proportion of the structural unit (III) contained in the polymer (A) is preferably no less than 0 mol % and no greater than 30 mol %, and more preferably no less than 0 mol % and no greater than 20 mol %. When the proportion of the structural unit (III) falls within the above range, the photoresist composition can have improved sensitivity.

### [Structural Unit (IV)]

The polymer (A) may have a structural unit (IV) containing a fluorine atom. Although the polymer (A) is a fluorine atom-containing polymer, the fluorine atom contained in the polymer (A) may be included in the structural units (I) to (III) that the polymer (A) has, or may be included due to having the structural unit (IV). When the polymer (A) has the structural unit (IV), the photoresist composition can have sufficiently satisfactory water repellency.

The structural unit (IV) is exemplified by a structural unit represented by the following formula (3), and the like.

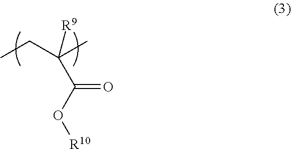

In the above formula (3), R⁹ represents a hydrogen atom, a fluorine atom, a methyl group or a trifluoromethyl group; R¹⁰ represents an alkyl group having 1 to 6 carbon atoms having a fluorine atom, or a monovalent alicyclic hydrocarbon group having 4 to 20 carbon atoms and having a fluorine atom, wherein a part or all of hydrogen atoms of the alkyl group and the alicyclic hydrocarbon group are unsubstituted or optionally substituted.

The structural unit (IV) is exemplified by structural units represented by the following formulae (3-1) and (3-2), and the like.

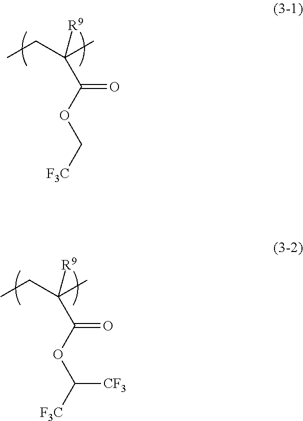

In the above formulae (3-1) and (3-2), R⁹ is as defined in connection with the above formula (3).

Examples of the monomer that gives the structural unit (IV) include trifluoromethyl(meth)acrylate, 2,2,2-trifluoroethyl(meth)acrylate, perfluoroethyl(meth)acrylate, perfluoro n-propyl(meth)acrylate, perfluoro i-propyl(meth)acrylate, perfluoro n-butyl(meth)acrylate, perfluoro i-butyl(meth)acrylate, perfluoro t-butyl(meth)acrylate, perfluorocyclohexyl(meth)acrylate, 2-(1,1,1,3,3,3-hexafluoro)propyl(meth)acrylate, 1-(2,2,3,3,4,4,5,5-s octafluoro)pentyl(meth)acrylate, 1-(2,2,3,3,4,4,5,5-octafluoro)hexyl(meth)acrylate, perfluorocyclohexylmethyl(meth)acrylate, 1-(2,2,3,3,3-pentafluoro)propyl(meth)acrylate, 1-(2,2,3,3,4,4,4-heptafluoro)penta(meth)acrylate, 1-(3,3,4,4,5,5,6,6,7,7,8,8,9,9,10,10,10-n heptadecafluoro)decyl(meth)acrylate, 1-(5-trifluoromethyl-3,3,4,4,5,6,6,6-octafluoro)hexyl(meth)acrylate, and the like.

In the polymer (A), the content of the structural unit (IV) is preferably no less than 0 mol % and no greater than 70 mol %, and more preferably no less than 0 mol % and no greater than 50 mol %.

The content of fluorine atoms of the polymer (A) is preferably no less than 5% by mass and no greater than 50% by mass, more preferably no less than 10% by mass and no greater than 40% by mass, and still more preferably no less than 15% by mass and no greater than 30% by mass. When the content of fluorine atoms of the polymer (A) falls within the specified range, the photoresist composition can have sufficiently satisfactory water repellency.

### <Synthesis Method of Polymer (A)>

The polymer (A) may be produced by, for example, polymerizing a monomer corresponding to each certain structural unit in an appropriate solvent using a radical polymerization initiator. The polymer (A) is preferably synthesized according to a method such as, e.g.: a method in which a solution containing a monomer and a radical initiator is added dropwise to a solution containing a reaction solvent or a monomer to permit a polymerization reaction; a method in which a solution containing a monomer, and a solution containing a radical initiator are each separately added dropwise to a solution containing a reaction solvent or a monomer to permit a polymerization reaction; or a method in which a plurality of solutions each containing a monomer, and a solution containing a radical initiator are each separately added dropwise to a solution containing a reaction solvent or a monomer to permit a polymerization reaction.

The reaction temperature in these methods may be determined ad libitum depending on the type of the initiator species. The reaction temperature is usually 30° C. to 180° C., preferably 40° C. to 160° C., and more preferably 50° C. to 140° C. Time period for the dropwise addition may vary depending on the conditions such as the reaction temperature, the type of the initiator and the monomer to be reacted, and is usually 30 min to 8 hrs, preferably 45 min to 6 hrs, and more preferably 1 hour to 5 hrs. Further, the total reaction time period including time period for dropwise addition may also vary depending on the conditions similarly to the time period for the dropwise addition, and is usually 30 min to 8 hrs, preferably 45 min to 7 hrs, and more preferably 1 hour to 6 hrs.

The radical initiator for use in the polymerization is exemplified by azobisisobutyronitrile (AIBN), 2,2′-azobis(4-methoxy-2,4-dimethylvaleronitrile), 2,2′-azobis(2-cyclopropyl propionitrile), 2,2′-azobis(2,4-dimethylvaleronitrile), 2,2′-azobis(2-methylpropionitrile), and the like. These initiators may be used as a mixture of two or more thereof.

A polymerization solvent is not limited as long as the solvent is other than solvents that inhibit polymerization (nitrobenzene having a polymerization inhibitory effect, a mercapto compound having a chain transfer effect, etc.), and is capable of dissolving the monomer. Examples of the polymerization solvent include alcohol solvents, ketone solvents, amide solvents, ester-lactone solvents, nitrile solvents and mixed solvents thereof, and the like. These solvents may be used either alone, or in combination of two or more thereof.

The polymer obtained by the polymerization reaction may be recovered preferably by a reprecipitation technique. More specifically, after the polymerization reaction is completed, the polymerization mixture is charged into a solvent for reprecipitation, whereby a target polymer is recovered in the form of powder. As the reprecipitation solvent, an alcohol, an alkane or the like may be used either alone or as a mixture of two or more thereof. Alternatively to the reprecipitation technique, liquid separating operation, column operation, ultrafiltration operation or the like may be employed to recover the polymer through eliminating low molecular components such as monomers and oligomers.

Although the polystyrene equivalent weight average molecular weight (Mw) of the polymer (A) as determined by gel permeation chromatography (GPC) is not particularly limited, it is preferably no less than 1,000 and no greater than 500,000, and more preferably no less than 2,000 and no greater than 400,000. It is to be noted that when the Mw of the polymer (A) is less than 1,000, heat resistance of the resulting resist is likely to be inferior. On the other hand, when the Mw of the polymer (A) exceeds 500,000, developability of the resulting resist is likely to be inferior.

In addition, the ratio (Mw/Mn) of the Mw to the polystyrene equivalent number average molecular weight (Mn) as determined by GPC of the polymer (A) is typically 1 or greater and 5 or less, preferably 1 or greater and 3 or less, and more preferably 1 or greater and 2 or less. When the ratio Mw/Mn falls within such a range, the photoresist film becomes superior in resolving abilities.

It is to be noted that the Mw and Mn as referred to herein means a value determined by gel permeation chromatography (GPC) using GPC columns (manufactured by Tosoh Corporation, G2000HXL×2, G3000HXL×1, G4000HXL×1), under analysis conditions involving a flow rate of 1.0 mL/min, an elution solvent of tetrahydrofuran and a column temperature of 40° C. using mono-dispersed polystyrene as a standard.

The content of the polymer (A) in the photoresist composition is preferably no less than 0.1 parts by mass and no greater than 10 parts by mass, and more preferably no less than 1 part by mass and no greater than 8 parts by mass with respect to 100 parts by mass of the polymer (C) described later. When the content of the polymer (A) falls within the specified range, the resist film formed from the photoresist composition has sufficiently satisfactory water repellency, and can suppress generation of development defects.

### <(B) Polymer>

The polymer (B) is a fluorine atom-containing polymer having a structural unit (II) that includes an alkali-dissociable group. In the photoresist composition, since the polymer (B) has a structural unit (II), an affinity with a developer solution can be improved in an alkali development, whereby development defects can be suppressed. In addition to the structural unit (II), the polymer (B) may have the structural unit (III) that includes an acid-dissociable group and/or a structural unit (IV) containing a fluorine atom, etc. It is preferred that the polymer (B) does not have the structural unit (I). The polymer (B) may have either one type of each structural unit alone, or two or more types thereof. Hereinafter, each structural unit will be described in detail.

### [Structural Unit (II)]

The structural unit (II) includes an alkali-dissociable group. The structural unit (II) is not particularly limited as long as it is a structural unit that is dissociated by an alkaline developer used in a development step in the method for forming a resist pattern to generate a polar group such as a carboxy group, and is preferably the structural unit represented by the above formula (2).

In the above formula (2), R⁴ represents a hydrogen atom, a fluorine atom, a methyl group or a trifluoromethyl group; R⁵ represents a hydrocarbon group having a valency of (n+1) and having 1 to 20 carbon atoms; R⁶ represents a single bond, a bivalent hydrocarbon group having 1 to 20 carbon atoms or a bivalent heterocyclic group having 4 to 20 carbon atoms; R⁷ represents a monovalent hydrocarbon group having 1 to 20 carbon atoms; Y represents —CO—O—* or —O—CO—*, “*” denotes a site bound to R⁷; n is an integer of 1 to 3, wherein provided that n is 2 or greater, a plurality of R⁶s, R⁷s and Ys may be each the same or different, and a part or all of hydrogen atoms that the hydrocarbon group represented by R⁵, R⁶ and R⁷ has are unsubstituted or optionally substituted.

With respect to the hydrocarbon group having a valency of (n+1) and having 1 to 20 carbon atoms represented by the R⁵, details of the hydrocarbon group having a valency of (m+1) and having 1 to 20 carbon atoms represented by the R² in the above formula (1) may be adopted with “m” replaced with “n”.

With respect to the bivalent hydrocarbon group having 1 to 20 carbon atoms represented by the R⁶, details of the bivalent hydrocarbon group having 1 to 20 carbon atoms represented by the R³ in the above formula (1) may be adopted.

The bivalent heterocyclic group having 4 to 20 carbon atoms represented by the R⁶ is exemplified by a group in which at least one bond selected from an —O— bond, a —S— bond, a —COO— bond, a —CO— bond, a —SO₃ bond and a —SO₂ bond is combined with a hydrocarbon group. Specific examples of the bivalent heterocyclic group having 4 to 20 carbon atoms include groups derived by removing two hydrogen atoms from a lactone such as β-propiolactone, γ-butyrolactone, δ-valerolactone or norbornanelactone, groups derived by removing two hydrogen atoms from a sultone such as pentane-2,5-sultone or norbornanesultone, and the like.

The monovalent hydrocarbon group having 1 to 20 carbon atoms represented by the R⁷ is exemplified by a linear or branched alkyl group having 1 to 20 carbon atoms, an alicyclic hydrocarbon group having 4 to 20 carbon atoms, and the like.

Examples of the linear or branched alkyl group having 1 to 20 carbon atoms include a methyl group, an ethyl group, a propyl group, a n-butyl group, an i-butyl group, a n-pentyl group, an i-pentyl group, a n-hexyl group, an i-hexyl group, a n-decyl group, an i-dodecyl group, and the like.

Examples of the alicyclic hydrocarbon group having 4 to 20 carbon atoms include a cyclobutyl group, a cyclopentyl group, a cyclohexyl group, a cyclodecyl group, a norbornyl group, an adamantyl group, and the like.

The “n” is preferably 1 or 2, and more preferably 1.

The structural unit (II) is exemplified by a structural unit represented by the following formula, and the like.

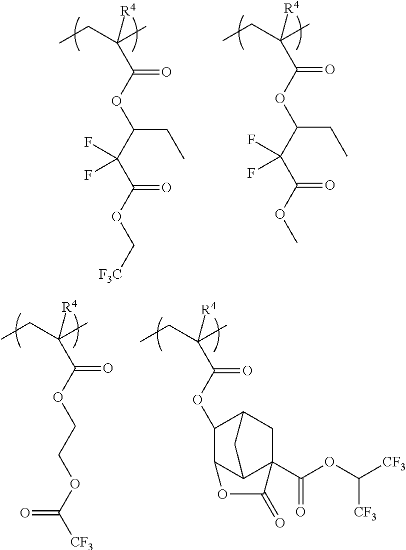

In the above formulae, R⁴ is as defined in connection with the above formula (2).

Examples of the monomer that gives the structural unit (II) include monomers represented by the following formulae, and the like.

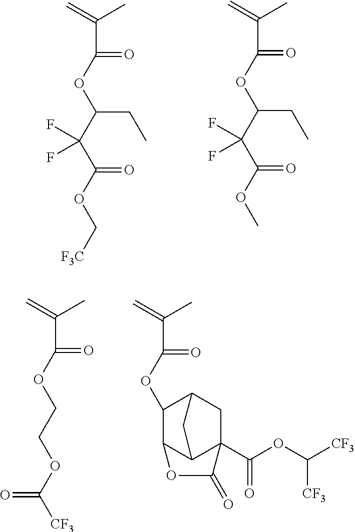

The content of the structural unit (II) in the polymer (B) is preferably no less than 10 mol % and no greater than 100 mol %, more preferably no less than 30 mol % and no greater than 99 mol %, still more preferably no less than 50 mol % and no greater than 98 mol %, and particularly preferably no less than 70 mol % and no greater than 95 mol %. When the polymer (B) has the structural unit (II) falling with in the specified range, the photoresist composition enables generation of development defects to be suppressed.

### [Structural Unit (III)]

The polymer (B) may also have a structural unit (III) that includes an acid-dissociable group. When the polymer (B) further has the structural unit (III), the photoresist composition can have improved sensitivity. It is to be noted that with respect to the structural unit (III), details of the structural unit (III) in the polymer (C) described later may be adopted.

The proportion of the structural unit (III) contained in the polymer (B) is preferably no less than 0 mol % and no greater than 30 mol %, and more preferably no less than 5 mol % and no greater than 20 mol %. When the proportion of the structural unit (III) falls within the above range, the photoresist composition can have improved sensitivity.

### [Structural Unit (IV)]

The polymer (B) may have a structural unit (IV) containing a fluorine atom. When the polymer (B) further has the structural unit (IV), the resist film formed from the photoresist composition can improve water repellency. It is to be noted that with respect to the structural unit (IV), details of the structural unit (IV) in the polymer (A) may be adopted.

The content of the structural unit (IV) in the polymer (B) is preferably no less than 0 mol % and no greater than 70 mol %, and more preferably no less than 0 mol % and no greater than 50 mol %.

The content of fluorine atoms of the polymer (B) is preferably no less than 5% by mass and no greater than 50% by mass, more preferably no less than 10% by mass and no greater than 40% by mass, and still more preferably no less than 15% by mass and no greater than 30% by mass. When the content of fluorine atoms of the polymer (B) falls within the specified range, the photoresist composition can have sufficiently satisfactory water repellency.

### <Synthesis Method of Polymer (B)>

The polymer (B) may be produced by, for example, polymerizing a monomer corresponding to each certain structural unit in an appropriate solvent using a radical polymerization initiator. It is to be noted that a polymerization initiator, a solvent and the like used in the synthesis of the polymer (B) may be exemplified by similar to those exemplified for the synthesis method of the polymer (A).

The reaction temperature in the polymerization described above is typically 40° C. to 150° C., and preferably 50° C. to 120° C. The reaction time is typically 1 hour to 48 hrs, and preferably 1 hour to 24 hrs.

The polystyrene equivalent weight average molecular weight (Mw) of the polymer (B) as determined by a gel permeation chromatography (GPC) method is preferably 1,000 to 50,000, more preferably 2,000 to 30,000, and particularly preferably 3,000 to 10,000. When the Mw of the polymer (B) is less than 1,000, attaining a sufficient advancing contact angle fails. On the other hand, when the Mw exceeds 50,000, developability when produced into a resist is likely to be deteriorated.

A ratio (Mw/Mn) of the Mw to the polystyrene equivalent number average molecular weight (Mn) as determined by a GPC method of the polymer (B) is typically 1 to 3, and preferably 1 to 2.

The content of the polymer (B) in the photoresist composition is preferably no less than 0.1 parts by mass and no greater than 10 parts by mass, and more preferably no less than 1 part by mass and no greater than 8 parts by mass with respect to 100 parts by mass of the polymer (C) described later. When the content of the polymer (B) falls within the specified range, the resist film formed from the photoresist composition has sufficiently satisfactory water repellency, and can suppress generation of development defects.

The mass ratio of the polymer (A) to the polymer (B) in the photoresist composition is preferably no less than 0.2 and no greater than 2.0, and more preferably no less than 0.5 and no greater than 1.5. When the photoresist composition contains the polymer (A) and the polymer (B) at a mass ratio falling within the specified range, the formed resist film has sufficiently satisfactory water repellency, and generation of development defects can be suppressed.

### <(C) Polymer>

The polymer (C) typically accounts for no less than 50% by mass in the polymer contained in the photoresist composition. The polymer (C) preferably has a structural unit (III) that includes an acid-dissociable group. When the polymer (C) has the structural unit (III), the acid-dissociable group is dissociated by an action of an acid generated from the acid generating agent upon exposure, leading to a change of the polarity of the polymer, whereby an increase of a solubility of the polymer (C) in an alkaline developer at the light-exposed site is enabled. It is preferred that the polymer (C) further has a structural unit (V) that includes at least one group selected from the group consisting of a lactone group, a cyclic carbonate group and a sultone group, and/or the structural unit (I) that includes a hydrophilic group, in addition to the structural unit (III). Also, the polymer (C) may have other structural unit as long as the effects of the invention are not impaired. It is to be noted that the content of fluorine atoms of the polymer (C) is preferably lower than those of the polymer (A) and the polymer (B). The polymer (C) may have either one type of each structural unit alone, or two or more types thereof. Hereinafter, each structural unit will be described in detail.

### [Structural Unit (III)]

The structural unit (III) includes an acid-dissociable group, and is preferably a structural unit represented by the following formula (4).

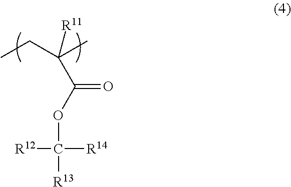

In the above formula (4), R¹¹ represents a hydrogen atom, a fluorine atom, a trifluoromethyl group or an alkyl group having 1 to 3 carbon atoms; R¹² to R¹⁴ each independently represent an alkyl group having 1 to 4 carbon atoms or an alicyclic group having 4 to 20 carbon atoms, wherein, R¹³ and R¹⁴ may bind to each other to form a bivalent alicyclic group having 4 to 20 carbon atoms together with the carbon atom to which R¹³ and R¹⁴ bond.

Examples of the alkyl group having 1 to 4 carbon atoms represented by the R¹² to R¹⁴ include a methyl group, an ethyl group, a n-propyl group, an i-propyl group, a n-butyl group, an i-butyl group, a tert-butyl group, a 2-methylpropyl group, a 1-methylpropyl group, and the like.

The alicyclic group having 4 to 20 carbon atoms, and the alicyclic group which may be formed by binding of R¹³ and R¹⁴ with each other together with the carbon atom to which they bond are exemplified by a polycyclic alicyclic group having a bridged skeleton such as an adamantane skeleton or a norbornane skeleton; a monocyclic alicyclic group having a cycloalkane skeleton such as cyclopentane or cyclohexane. In addition, these groups are unsubstituted or optionally substituted with, for example, at least one or more types of linear, branched or cyclic alkyl groups having 1 to 10 carbon atoms.

The structural unit (III) is preferably a structural unit represented by the following formulae.

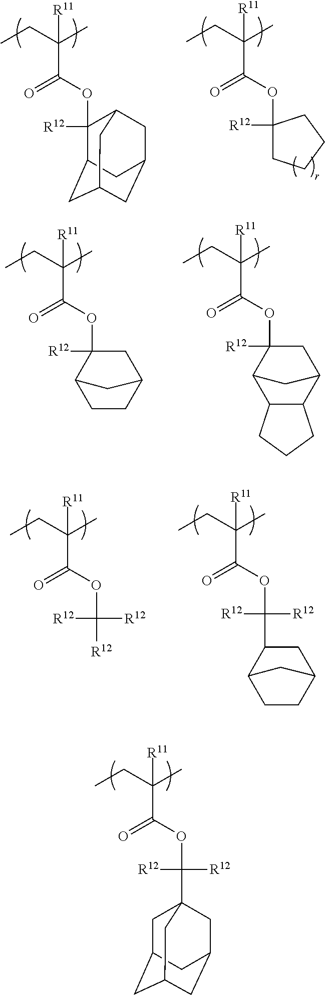

In the above formulae, R¹¹ is as defined in connection with the above formula (4); R¹² represents an alkyl group having 1 to 4 carbon atoms; and r is an integer of 1 to 6.

Of these, structural units represented by the following formulae (3-1) to (3-20) are preferred.

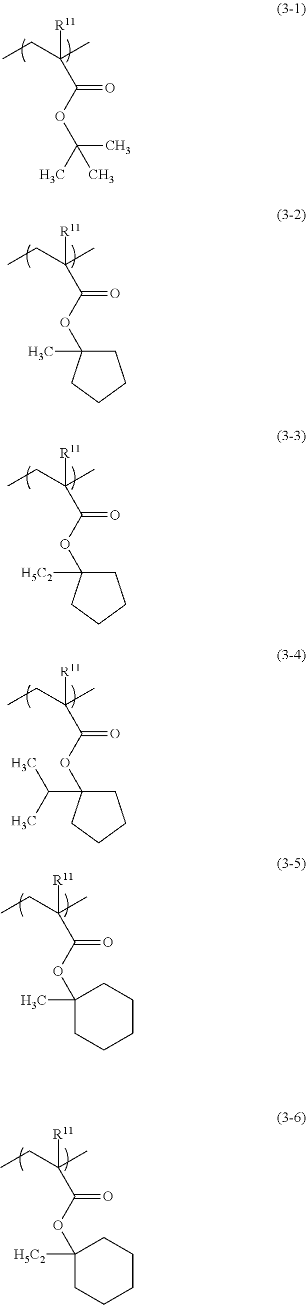

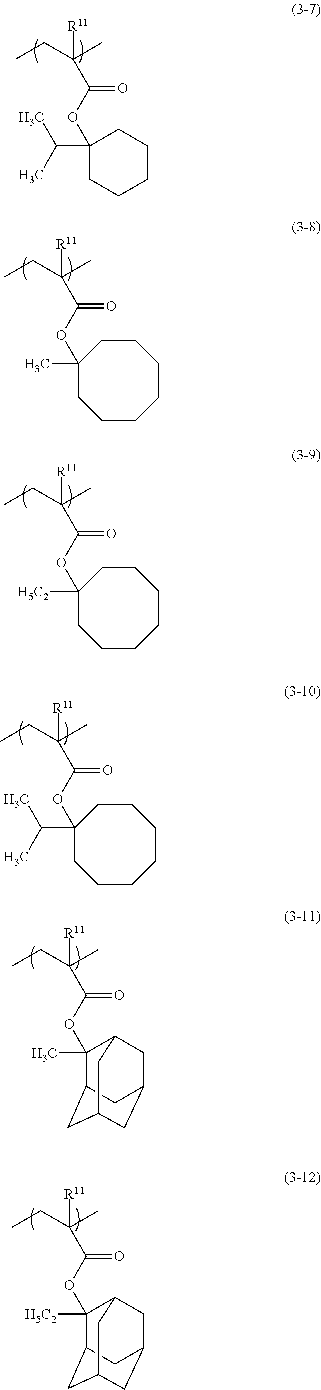

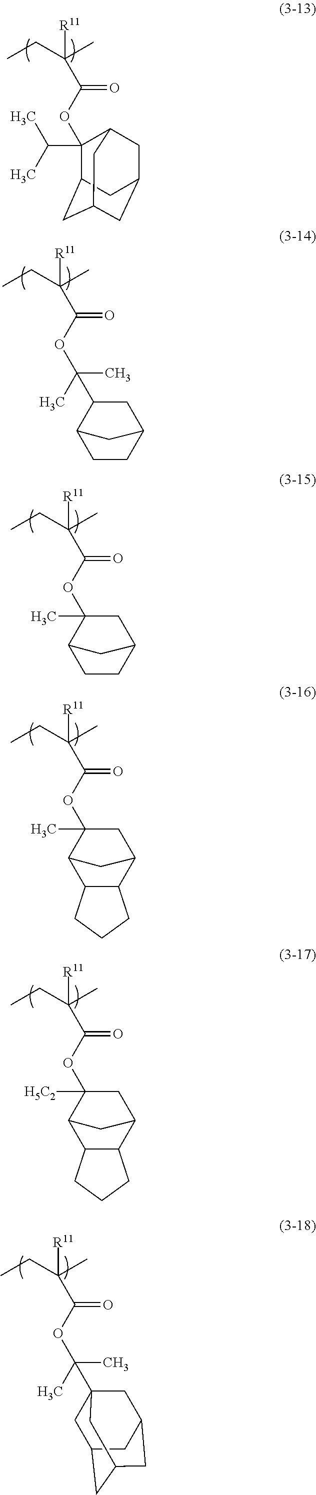

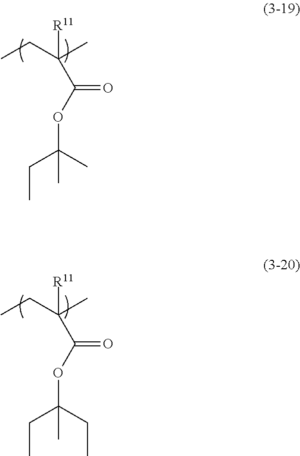

In the above formulae, R¹¹ is as defined in connection with the above formula (4).

Of these, structural units represented by the above formulae (3-2), (3-3), (3-9) and (3-12) are more preferred.

Examples of the monomer that gives the structural unit (III) include monomers that include an acid-dissociable group having a monocyclic alicyclic group such as a 1-alkyl-cycloalkyl ester, monomers that include an acid-dissociable group having a polycyclic alicyclic group such as a 2-alkyl-2-n dicycloalkyl ester, and the like.

In the polymer (C), the proportion of the structural unit (III) contained is preferably 5 mol % to 80 mol %, more preferably 10 mol % to 80 mol %, and still more preferably 20 mol % to 70 mol %. Due to the proportion of the structural unit (III) falling within the above range, the photoresist composition can have superior sensitivity.

### [Structural Unit (V)]

The polymer (C) preferably has a structural unit (V) that includes a lactone group, a cyclic carbonate group or a sultone group. When the polymer (C) further has the structural unit (V), the resist film formed from the photoresist composition can have improved adhesiveness to a substrate. Herein, the lactone group refers to a group having one ring (lactone ring) that includes a structure represented by: —O—C(O)—. Also, the cyclic carbonate group refers to a group having one ring (cyclic carbonate ring) that includes a structure represented by: —O—C(O)—O—. The sultone group refers to a group having one ring (sultone ring) that includes a structure represented by: —O—SO₂—. It is to be noted that assuming that the lactone ring, cyclic carbonate ring or sultone ring is a first ring, when a group has only a lactone ring, cyclic carbonate ring or sultone ring, the group is deemed to be a monocyclic group, whereas when a group further has any additional other ring structure, the group is deemed to be a polycyclic group irrespective of the structure thereof. Among the structural units that include a lactone group, a cyclic carbonate group or a sultone group, those included in the structural unit (I) and the structural unit (II) are excluded from the structural unit (V).

The structural unit (V) is exemplified by structural units represented by the following formulae, and the like.

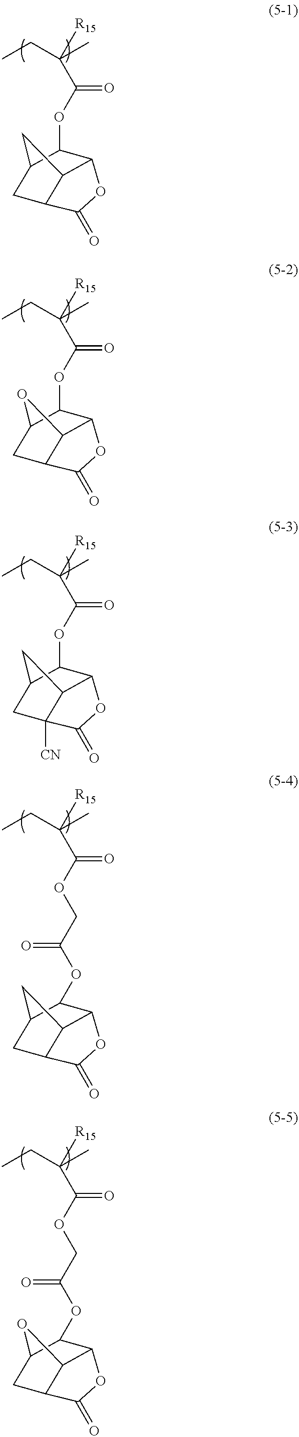

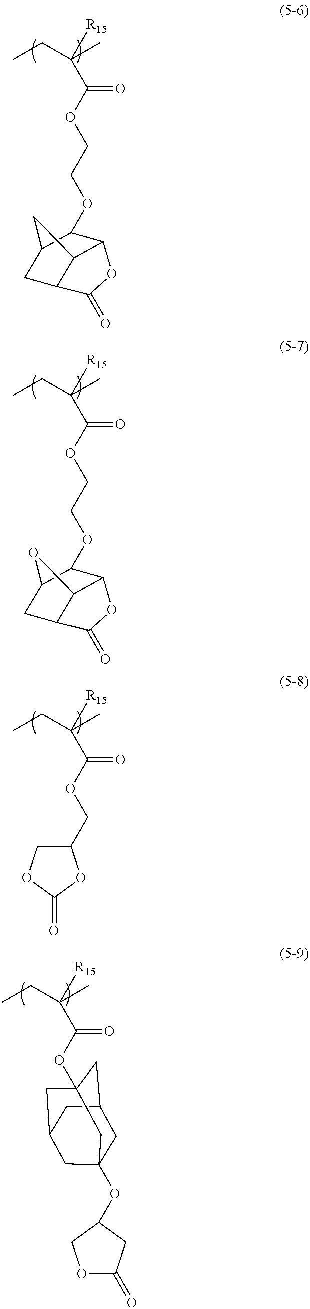

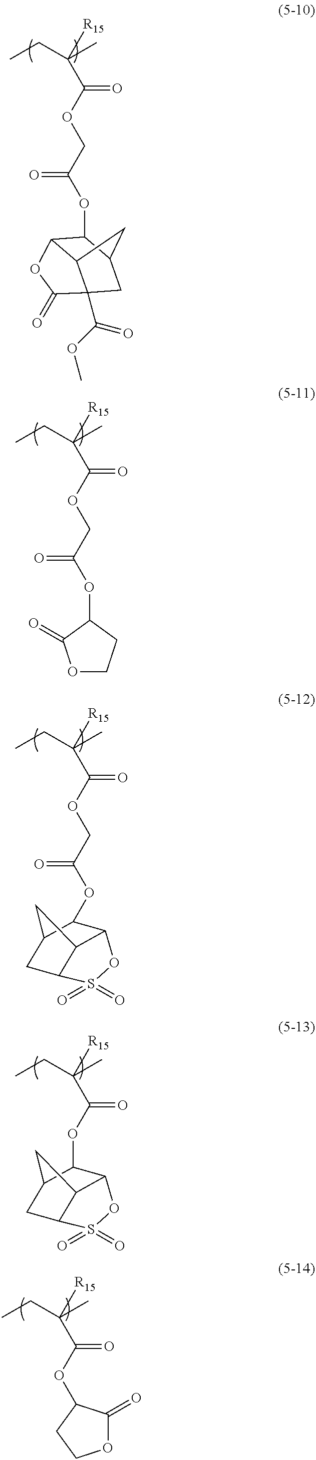

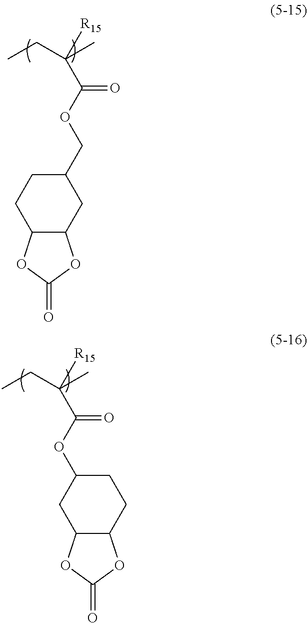

In the above formulae, R¹⁵ represents a hydrogen atom, a fluorine atom, a methyl group or a trifluoromethyl group.

Of these, in light of improvement of the adhesiveness of the resist film, the structural unit represented by the above formula (5-1) is preferred.

Examples of the monomer compound that gives the structural unit (V) include compounds represented by the following formulae.

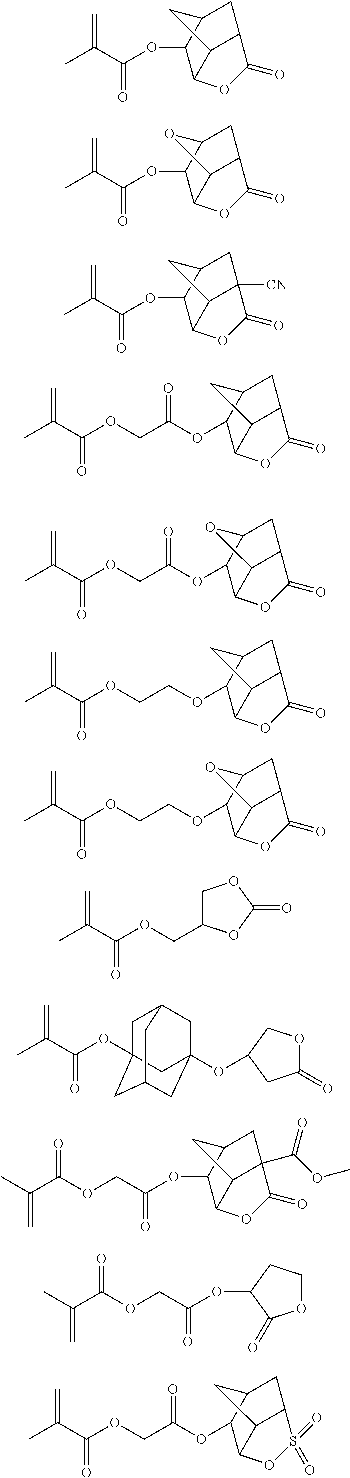

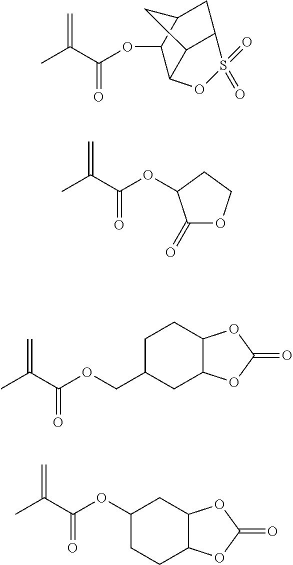

The content of the structural unit (V) in the polymer (C) is preferably no less than 10 mol % and no greater than 80 mol %, and more preferably no less than 20 mol % and no greater than 70 mol %. When the content of the structural unit (V) falls within the above range, the resist film obtained from the photoresist composition can have improved adhesiveness to a substrate, etc.

### [Structural Unit (I)]

The polymer (C) preferably has the structural unit (I). When the polymer (C) further has the structural unit (I), the photoresist composition can have improved lithography performance. It is to be noted that the monomer that gives the structural unit (I) to be included in the polymer (C) is exemplified by hydroxyalkyl(meth)acrylates such as 2-hydroxyethyl(meth)acrylate, 2-hydroxypropyl(meth)acrylate, 3-hydroxypropyl(meth)acrylate and 2-hydroxyadamantyl(meth)acrylate, and the like.

The proportion of the structural unit (I) contained in the polymer (C) is preferably 0 mol % to 30 mol %, and more preferably 5 mol % to 20 mol %.

### <Synthesis Method of Polymer (C)>

The polymer (C) may be produced by, for example, polymerizing a monomer corresponding to each certain structural unit in an appropriate solvent using a radical polymerization initiator. It is to be noted that a polymerization initiator, a solvent and the like used in the synthesis of the polymer (B) may be exemplified by similar to those exemplified for the synthesis method of the polymer (A).

The reaction temperature in the polymerization described above is typically 40° C. to 150° C., and preferably 50° C. to 120° C. The reaction time is typically 1 hour to 48 hrs, and preferably 1 hour to 24 hrs.

The polystyrene equivalent weight average molecular weight (Mw) of the polymer (C) as determined by a gel permeation chromatography (GPC) method is preferably 1,000 to 50,000, more preferably 2,000 to 30,000, and particularly preferably 3,000 to 10,000. When the Mw of the polymer (C) is less than 1,000, attaining the sensitivity fails. On the other hand, when the Mw exceeds 50,000, developability when produced into a resist is likely to be deteriorated.

The ratio (Mw/Mn) of the Mw to the polystyrene equivalent number average molecular weight (Mn) as determined by a GPC method of the polymer (C) is typically 1 to 3, and preferably 1 to 2.

The proportion of the polymer (C) contained with respect to the total of the polymers is preferably no less than 50% by mass and no greater than 99.5% by mass, more preferably no less than 70% by mass and no greater than 99% by mass, and still more preferably no less than 80% by mass and no greater than 98% by mass.

### <(D) Acid Generator>

The acid generator (D) is a compound that generates an acid by light that transmitted through a mask in an exposure step that is one step of resist pattern formation. The form of the acid generator (D) included in the photoresist composition may be: a compound as described later (hereinafter, may be also referred to as “(D) acid generating agent” when included in such a form); a part of the polymer; or of both of these.

Examples of the acid generating agent (D) include onium salt compounds, sulfonimide compounds, halogen-containing compounds, diazoketone compounds, and the like. Among these acid generating agents (D), onium salt compounds are preferred.

Examples of the onium salt compound include sulfonium salts (including tetrahydrothiophenium salts), iodonium salts, phosphonium salts, diazonium salts, pyridinium salts, and the like. Of these, sulfonium salts (including tetrahydrothiophenium salts) and iodonium salts are more preferred.

Examples of the sulfonium salt include triphenylsulfonium adamantyloxycarbonyl-1,1-difluoromethanesulfonate, triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methane sulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, triphenylphosphonium 1,1,2,2-tetrafluoro-6-(1-adamantanecarbonyloxy)-hexane-1-sulfonate, and the like. Of these, triphenylsulfonium adamantyloxycarbonyl-1,1-difluoromethanesulfonate, triphenylsulfonium trifluoromethanesulfonate, triphenylsulfonium nonafluoro-n-butanesulfonate and triphenylphosphonium 1,1,2,2-tetrafluoro-6-(1-adamantanecarbonyloxy)-hexane-1-sulfonate are preferred.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, and the like. Of these, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate and 1-(3,5-dimethyl-4-hydroxyphenyl)tetrahydrothiophenium nonafluoro-n-butanesulfonate are preferred.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, and the like. Of these, bis(4-t-butylphenyl)iodonium nonafluoro-n-butanesulfonate is preferred.

These acid generating agents (D) may be used either alone, or in combination of at least two types thereof. In the case in which the acid generator (D) is the acid generating agent (D), the amount thereof used is, in light of securement the sensitivity and lithography performances of the resist film formed from the photoresist composition, preferably no less than 0.01 parts by mass and no greater than 25 parts by mass, and more preferably no less than 0.1 parts by mass and no greater than 20 parts by mass with respect to 100 parts by mass of the polymer (C).

### <(E) Acid Diffusion Controller>

The acid diffusion controller (E) is a component that exhibits an effect of controlling a phenomenon of diffusion of an acid, which is generated from the acid generator (D) upon exposure, in the resist film, and inhibiting an undesired chemical reaction in an unexposed portion. Inclusion of the acid diffusion controller (E) in the photoresist composition enables the storage stability of the resulting photoresist composition to be further improved and the resolving abilities of the resist to be further improved. In addition, an alteration of line width of the resist pattern due to varying post-exposure delay (PED) from the exposure to the development process to be prevented so that a composition that exhibits excellent process stability can be obtained. It is to be noted that the acid diffusion controller (E) may be contained in the photoresist composition according to the embodiment of the present invention in a free compound form (hereinafter, may be also appropriately referred to as “(E) acid diffusion control agent”) or in an incorporated form as a part of the polymer, or in both of these forms.

Examples of the acid diffusion control agent (E) include amine compounds, amide group-containing compounds, urea compounds, nitrogen-containing heterocyclic compounds, and the like.

Examples of the amine compound include mono(cyclo)alkylamines; di(cyclo)alkylamines; tri(cyclo)alkylamines; substituted alkylaniline and derivatives thereof; ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis(1-(4-aminophenyl)-1-methylethyl)benzene, 1,3-bis(1-(4-aminophenyl)-1-methylethyl)benzene, bis(2-dimethylaminoethyl)ether, bis(2-diethylaminoethyl)ether, 1-(2-hydroxyethyl)-2-imidazolidinone, 2-quinoxalinol, N,N,N′,N′-tetrakis(2-hydroxypropyl)ethylenediamine, N,N,N′,N″N″-pentamethyldiethylenetriamine, triethanolamine, and the like.

Examples of the amide group-containing compound include N-t-butoxycarbonyl group-containing amino compounds, formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl)isocyanurate, and the like.

Examples of the urea compound include urea, methylurea, 1,1-dimethylurea, 1,3-dimethylurea, 1,1,3,3-tetramethylurea, 1,3-diphenylurea, tri-n-butylthiourea, and the like.

Examples of the nitrogen-containing heterocyclic compound include imidazoles; pyridines; piperazines; pyrazine, pyrazole, pyridazine, quinoxaline, purine, pyrrolidine, piperidine, 4-hydroxy-N-amyloxycarbonypiperidine, piperidine ethanol, 3-piperidino-1,2-propanediol, morpholine, 4-methylmorpholine, 1-(4-morpholinyl)ethanol, 4-acetyl morpholine, 3-(N-morpholino)-1,2-propanediol, 1,4-dimethylpiperazine, 1,4-diazabicyclo[2.2.2]octane, N-t-butoxycarbonyl-4-hydroxypiperidine, and the like.

Moreover, a photodegradable base that generates a weak acid through sensitization upon exposure may be also used as the acid diffusion control agent (E). The photodegradable base generates an acid at light-exposed sites, whereby insolubility of the polymer (C) in the developer solution increases, and consequently roughness of the surface at the light-exposed sites after the development can be suppressed. On the other hand, the photodegradable base exerts a high acid-capturing function by an anion at light-unexposed sites and serves as a quencher, and captures the acid diffused from light-exposed sites. In other words, since the photodegradable base serves as a quencher at only light-unexposed sites, the contrast in a deprotection reaction is improved, and as a result, resolving abilities can be further improved. Exemplary photodegradable bases include onium salt compounds that lose acid-diffusion controllability through degradation due to an exposure. Examples of the onium salt compounds include sulfonium salt compounds represented by the following formula (E1), iodonium salt compounds represented by the following formula (E2), and the like.

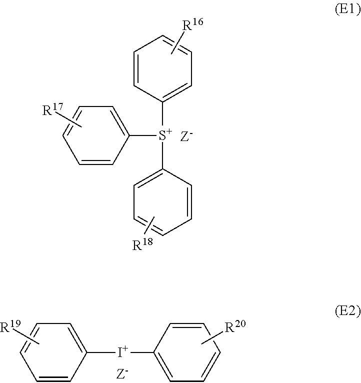

In the above formula (E1) and formula (E2), R¹⁶ to R²⁰ each independently represent a hydrogen atom, an alkyl group, an alkoxy group, a hydroxyl group, a halogen atom or —SO₂—R^{C}; R^{C} represents an alkyl group, a cycloalkyl group, an alkoxy group or an aryl group; Z⁻ represents an anion expressed by OH⁻, R²¹—COO⁻, R^{D}—SO₂—N⁻—R²¹, R²¹—SO₃⁻ or the following formula (E3); R²⁴ represents a linear or branched alkyl group having 1 to 10 carbon atoms, a cycloalkyl group having 3 to 20 carbon atoms, an aryl group having 6 to 30 carbon atoms or an alkaryl group having 7 to 30 carbon atoms, wherein a part or all of hydrogen atoms of the alkyl group, the cycloalkyl group, the aryl group and the alkaryl group are unsubstituted or optionally substituted; R^{D} represents a linear or branched alkyl group having 1 to 10 carbon atoms or a cycloalkyl group having 3 to 20 carbon atoms which may have a substituent, wherein a part or all of hydrogen atoms of the alkyl group and the cycloalkyl group are unsubstituted or optionally substituted by a fluorine atom, and provided that Z⁻ represents R²¹—SO₃⁻, any case where a fluorine atom binds to the carbon atom to which SO₃⁻ bonds is excluded.

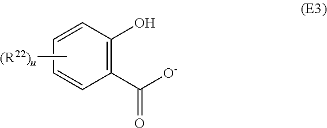

In the above formula (E3), R²² represents a linear or branched alkyl group having 1 to 12 carbon atoms in which a part or all of hydrogen atoms are unsubstituted or optionally substituted by a fluorine atom, or a linear or branched alkoxy group having 1 to 12 carbon atoms; and u is an integer of 0 to 2.

The content of the acid diffusion control agent (E) in the photoresist composition used in the method for forming a pattern is preferably less than 10 parts by mass, and more preferably less than 5 parts by mass with respect to 100 parts by mass of the polymer (C). When the content of the acid diffusion control agent (E) falls within the specified range, sensitivity as a resist is likely to be maintained. These acid diffusion control agents (E) may be used alone, or two or more thereof may be used in combination.

### <(F) Solvent>

The photoresist composition usually contains (F) a solvent. The solvent (F) is not particularly limited as long as it can dissolve at least the polymer (A) and the polymer (B), and favorable components, the polymer (C), the acid generator (D) and the acid diffusion control agent (E), as well as other optional components. The solvent (F) is exemplified by an alcohol solvent, an ether solvent, a ketone solvent, an amide solvent, an ester solvent, a hydrocarbon solvent and a mixed solvent thereof, and the like.

Examples of the Alcohol Solvent Include:
monohydric alcohol solvents such as methanol, ethanol, n-propanol, i-propanol, n-butanol, i-butanol, sec-butanol, tert-butanol, n-pentanol, i-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol and diacetone alcohol;
polyhydric alcohol solvents such as ethylene glycol, 1,2-propylene glycol, 1,3-butylene glycol, 2,4-pentanediol, 2-n methyl-2,4-pentanediol, 2,5-hexanediol, 2,4-heptanediol, 2-ethyl-1,3-hexanediol, diethylene glycol, dipropylene glycol, triethylene glycol and tripropylene glycol;
partially etherified polyhydric alcohol solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether; and the like.

Examples of the ether solvent include diethyl ether, dipropyl ether, dibutyl ether, diphenyl ether, and the like.

Examples of the ketone solvent include ketone solvents such as acetone, methyl ethyl ketone, methyl n-propyl ketone, methyl n-butyl ketone, diethyl ketone, methyl isobutyl ketone, methyl n-pentyl ketone, ethyl-n-butyl ketone, methyl n-hexyl ketone, di-isobutyl ketone, trimethylnonanone, cyclopentanone, cyclohexanone, cycloheptanone, cyclooctanone, methylcyclohexanone, 2,4-pentanedione, acetonylacetone, and acetophenone.

Examples of the amide solvent include N,N′-dimethylimidazolidinone, N-methylformamide, N,N-dimethylformamide, N,N-diethylformamide, acetamide, N-methylacetamide, N,N-dimethylacetamide, N-methylpropionamide, N-methylpyrrolidone, and the like.

Examples of the ester solvent include diethyl carbonate, propylene carbonate, methyl acetate, ethyl acetate, γ-butyrolactone, γ-valerolactone, n-propyl acetate, isopropyl acetate, n-butyl acetate, isobutyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, isoamyl propionate, diethyl oxalate, di-n-butyl oxalate, methyl lactate, ethyl lactate, n-butyl lactate, n-amyl lactate, diethyl malonate, dimethyl phthalate, diethyl phthalate, and the like.

Examples of the hydrocarbon solvent include:
aliphatic hydrocarbon solvents such as n-pentane, isopentane, n-hexane, isohexane, n-heptane, isoheptane, 2,2,4-trimethyl pentane, n-octane, isooctane, cyclohexane, and methylcyclohexane;
aromatic hydrocarbon solvents such as benzene, toluene, xylene, mesitylene, ethylbenzene, trimethylbenzene, methylethylbenzene, n-propylbenzene, isopropylbenzene, diethylbenzene, isobutylbenzene, triethylbenzene, di-isopropylbenzene, and n-amylnaphthalene; and the like.

Of these, propylene glycol monomethyl ether acetate, cyclohexanone and γ-butyrolactone are preferred. These solvents may be used alone, or two or more thereof may be used in combination.

### <Other Optional Components>

The photoresist composition may contain a surfactant, an alicyclic skeleton-containing compound, a sensitizer, and the like as other optional components. It is to be noted that the photoresist composition may contain only one type of the other optional components or two or more types of the other optional components.

### [Surfactant]

The surfactant achieves an effect of improving coating properties, striation, developability, and the like of the photoresist composition used for the method for forming a pattern.

### [Alicyclic Skeleton-Containing Compound]

The alicyclic skeleton-containing compound achieves an effect of ameliorating dry etching resistance, pattern configuration, adhesiveness to a substrate of the photoresist composition used for the method for forming a pattern.

### [Sensitizer]

The sensitizer exhibits an action of increasing the amount of formation of an acid from the acid generator (D) and achieves an effect of enhancing “apparent sensitivity” of the photoresist composition used for the method for forming a pattern.

### <Preparation Method of a Photoresist Composition>

The photoresist composition may be prepared by, for example, mixing the polymer (A), the polymer (B), the polymer (C), the acid generator (D), the acid diffusion control agent (E) and the other optional components at each predetermined proportion in the solvent (F). The photoresist composition is generally prepared upon use thereof by dissolving the components in the solvent such that the total solid content concentration becomes from 1% by mass to 30% by mass and preferably from 1.5% by mass to 25% by mass, and thereafter filtering through a filter having a pore size of for example, about 0.2 μm.

### <Method for Forming a Resist Pattern>

A method for forming a resist pattern using the photoresist composition of the embodiment of the present invention is explained below.

The method for forming a resist pattern includes:
(1) a step of forming a resist film on a substrate using the photoresist composition of the embodiment of the present invention (hereinafter, also referred to as “step (1)”),
(2) a step of exposing the resist film with liquid immersion lithography (hereinafter, also referred to as “step (2)”), and
(3) a step of developing the exposed resist film (hereinafter, also referred to as “step (3)”).

According to the method for forming a resist pattern, since the photoresist composition is used, satisfactory basic performances such as sensitivity can be attained, and the hydrophobicity can be sufficiently secured during liquid immersion lithography, whereas an affinity with the alkaline developer can be improved in the development step, and thus generation of development defects can be suppressed. Hereinafter, each step will be described in detail.

### [Step (1)]

In this step, the photoresist composition is coated by a means for coating such as spin coating, cast coating or roll coating on a substrate such as a silicon wafer, or a wafer covered with silicon dioxide or an antireflective film so as to give a predetermined film thickness, and in some instances a solvent in a coating film is volatilized by prebaking (PB) at a temperature of typically about 70° C. to 160° C. to form a resist film.

### [Step (2)]

In this step, the resist film formed in the step (1) is exposed by irradiating with a radioactive ray via a liquid immersion medium such as water. In this step, the radioactive ray is irradiated through a mask having a predetermined pattern. The radioactive ray appropriately selected from visible light rays, ultraviolet rays, deep ultraviolet rays, an X-ray, charged particle rays, EUV light and the like in accordance with the line width of the intended pattern may be irradiated. Of these far ultraviolet rays typified by ArF excimer laser light (wavelength: 193 nm) and KrF excimer laser light (wavelength: 248 nm) are preferred, and even a light source for EUV (extreme ultraviolet light, wavelength: 13.5 nm), etc., capable of forming a finer pattern can be suitably used. Next, post exposure baking (PEB) is preferably carried out. The PEB enables elimination of the acid-dissociable group included in the polymer (C), etc. to smoothly proceed. Heating conditions of PEB may be appropriately selected in accordance with the formulation of the photoresist composition, and typically include about 50° C. to 180° C.

### [Step (3)]

In this step, the exposed resist film is developed with a developer solution to form a resist pattern. After the development, washing with water and drying generally follow. Examples of preferable developer solution include aqueous alkali solutions prepared by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene or 1,5-diazabicyclo-[4.3.0]-5-nonene.

### <Method for Producing a Photoresist Composition>

The method for producing a photoresist composition of the embodiment of the present invention includes a step of mixing:
(A) a fluorine atom-containing polymer having a structural unit (I) that includes a hydrophilic group;
(B) a fluorine atom-containing polymer having a structural unit (II) that includes an alkali-dissociable group; and
(C) a polymer having an acid-dissociable group
(hereinafter, also referred to as “mixing step”).

Due to including the step of mixing the polymer (A), the polymer (B) and the polymer (C) in the method for producing a photoresist composition, while hydrophobicity can be sufficiently secured during liquid immersion lithography, an affinity with an alkaline developer can be improved in a development step according to the method for producing a photoresist composition; therefore, a photoresist composition capable of suppressing generation of development defects can be produced. With regard to the polymer (A), the polymer (B) and the polymer (C) used in the method for producing a photoresist composition, and the acid generator (D), the acid diffusion control agent (E), the solvent (F) and the other optional components used as needed, explanations of each component in the above item <Photoresist Composition> may be adopted.

In the mixing step, for example, the polymer (A), the polymer (B) and the polymer (C) are mixed in the solvent (F) that is a favorable component. With regard to a suitable combination of the structural unit (I) and the structural unit (II) in this mixing step, a suitable mass ratio of the polymer (A) to the polymer (B), the proportion of the polymer (C) contained, and a suitable content of the polymer (A) with respect to the polymer (C), and the like, explanations of each component in the above item <Photoresist Composition> may be adopted. Furthermore, in the mixing step, the acid generator (D), the acid diffusion control agent (E) and the other optional component(s) may be mixed at predetermined proportions, in addition to the polymers. The total solid content concentration of the obtained photoresist composition is typically 1% by mass to 30% by mass, and preferably 1.5% by mass to 25% by mass.

After the mixing step, the resulting mixture is preferably filtered through a filter having a pore size of 3 nm to 1.0 μm.

### EXAMPLES

Hereinafter, the present invention is explained in more detail by way of Examples, but the present invention is not limited to these Examples. Methods for determining various types of physical property values are shown below.

### [Weight Average Molecular Weight (Mw) and Number Average Molecular Weight (Mn)]

Mw and Mn were measured by gel permeation chromatography

(GPC) using GPC columns manufactured by Tosoh Corporation (G2000HXL×2, G3000HXL×1, G4000HXL×1) under analysis conditions including a flow rate of 1.0 mL/min, an elution solvent of tetrahydrofuran, a column temperature of 40° C., with mono-disperse polystyrene as a standard. In addition, the dispersity index (Mw/Mn) was derived from the results of determination of the Mw and Mn.

### [¹³C-NMR Analysis]

¹³C-NMR analysis was performed using JNM-EX270 (manufactured by JEOL, Ltd.).

### Synthesis of Polymer (A)

Monomer compounds used in synthesis of the polymer (A), and the polymer (B) and the polymer (C) described later are shown below.

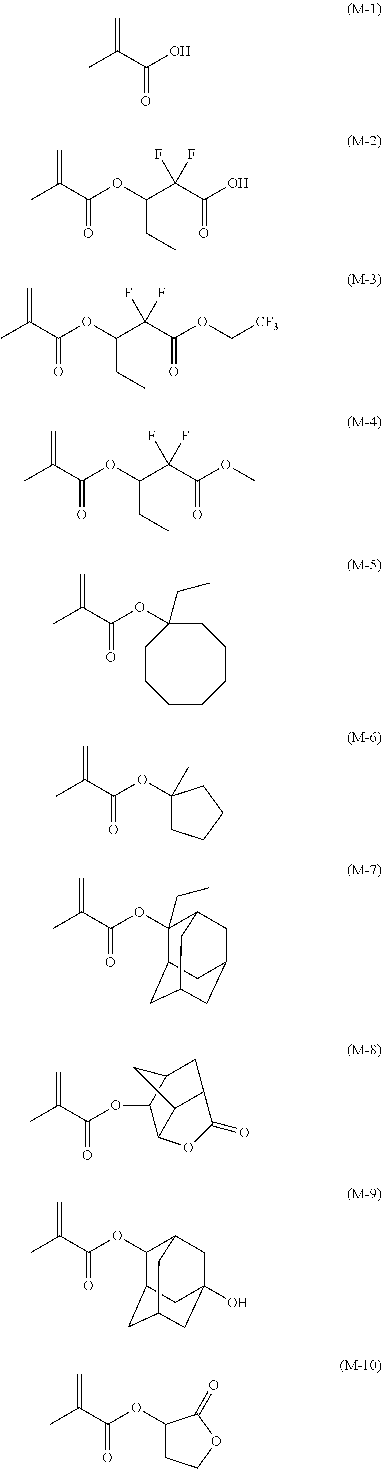

### Synthesis Example 1

In a 100 mL three-neck flask, 0.16 g of the compound (M-1) and 0.88 g of the compound (M-2) that give the structural unit (I), and 3.96 g of the compound (M-3) that gives the structural unit (II) were dissolved in 10 g of 2-butanone, and further 0.09 g of 2,2′-azobis(2-isobutyronitrile) was charged thereto. After nitrogen was purged for 30 min, the reaction vessel was heated to 80° C. with stirring, and the polymerizing reaction was carried out for 6 hrs from the start of heating. After the completion of the polymerization, the polymer solution was cooled with water to 30° C. or less, and concentrated in vacuo with an evaporator until the polymer solution had a mass of 12.5 g. The polymer liquid was slowly charged into 75 g of n-hexane which had been cooled to 0° C. to permit precipitation of the solid content. The mixture was filtered and the solid content was washed with n-hexane. The resulting powder was vacuum dried at 40° C. for 15 hrs to obtain 3.80 g of a white powder (polymer (A-1)) (yield: 76%). The obtained polymer (A-1) had an Mw of 9,400 and the dispersity index Mw/Mn of 1.50, and the ratio of the content of structural units derived from the compound (M-1), the compound (M-2) and the compound (M-3) in the polymer was 9.7:20.2:70.1 (mol %). The content of fluorine atoms was 27.9% by mass.

### Synthesis Examples 2 to 9

Polymers (A-2) to (A-9) were synthesized in a similar manner to Synthesis Example 1 except that monomers of the type shown in Table 1 were used with the blend formulation shown in Table 1. Note that the Mw, Mw/Mn, the yield, the proportion of the structural unit derived from each monomer in the polymer and results of measurement of the content of fluorine atoms of the obtained polymer are shown in Table 1 together.

### Synthesis of (B) Polymer

### Synthesis Example 10

In a 100 mL three-neck flask, 4.62 g of the compound (M-3) that gives the structural unit (II) (90 mol %) and 0.38 g of the compound (M-5) that gives the structural unit (III) (10 mol %) were dissolved in 10 g of 2-butanone, and further 0.08 g of 2,2′-azobis(2-isobutyronitrile) was charged thereto. After nitrogen was purged for 30 min, the reaction vessel was heated to 80° C. with stirring, and the polymerizing reaction was carried out for 6 hrs from the start of heating. After the completion of the polymerization, the polymer solution was cooled with water to 30° C. or less, and concentrated in vacuo with an evaporator until the polymer solution had a mass of 12.5 g. The polymer liquid was slowly charged into 75 g of n-hexane which had been cooled to 0° C., whereby the solid content was precipitated. The mixture was filtered and the solid content was washed with n-hexane. The resulting powder was vacuum dried at 40° C. for 15 hrs to obtain 3.75 g of a white powder (polymer (B-1)) (yield: 75%). The obtained polymer (B-1) had an Mw of 9,600 and the dispersity index Mw/Mn of 1.49, and the ratio of the content of structural units derived from the compound (M-3) and the compound (M-5) in the polymer was 88.5:11.5 (mol %). The content of fluorine atoms was 27.4% by mass.

### Synthesis Example 11

In a 100 mL three-neck flask, 4.52 g of the compound (M-4) that gives the structural unit (II) (90 mol %) and 0.48 g of the compound (M-5) that gives the structural unit (III) (10 mol %) were dissolved in 10 g of 2-butanone, and further 0.11 g of 2,2′-azobis(2-isobutyronitrile) was charged thereto. After nitrogen was purged for 30 min, the reaction vessel was heated to 80° C. with stirring, and the polymerizing reaction was carried out for 6 hrs from the start of heating. After the completion of the polymerization, the polymer solution was cooled with water to 30° C. or less, and concentrated in vacuo with an evaporator until the polymer solution had a mass of 12.5 g. The polymer liquid was slowly charged into 75 g of n-hexane which had been cooled to 0° C., whereby the solid content was precipitated. The mixture was filtered and the solid content was washed with n-hexane. The resulting powder was vacuum dried at 40° C. for 15 hrs to obtain 3.8 g of a white powder (polymer (B-2)) (yield: 76%). The obtained polymer (B-2) had an Mw of 11,200 and the dispersity index Mw/Mn of 1.51, and the ratio of the content of structural units derived from the compound (M-4) and the compound (M-5) in the polymer was 89.8:10.2 (mol %). The content of fluorine atoms was 14.6% by mass.

### Synthesis of Polymer (C)

### Synthesis Example 12

In 200 g of 2-butanone were dissolved 11.92 g of the compound (M-6) and 41.07 g of the compound (M-7) that give the structural unit (III), 15.75 g of the compound (M-8) and 20.10 g of the compound (M-10) that give the structural unit (V), 11.16 g of the compound (M-9) that gives the structural unit (I), and 3.88 g dimethyl 2,2′-azobis(2-isobutyronitrile). Into 1,000 mL three-neck flask was charged 100 g of 2-butanone, and after nitrogen was purged for 30 min, the reaction vessel was heated to 80° C. with stirring. The prepared solution was added dropwise thereto over 4 hrs, and then aged for at 80° C. for 2 hrs following completing the dropwise addition. After the completion of the polymerization, the polymer solution was cooled with water to 30° C. or less. The polymer solution was concentrated in vacuo with an evaporator until the polymer solution had a mass of 200 g. Thereafter, the polymer liquid was charged into 1,000 g of methanol to permit reprecipitation. The precipitated slurry was filtered off by vacuum filtration, and the solid content was washed three times with methanol. The resulting powder was vacuum dried at 60° C. for 15 hrs to obtain 88.0 g of a white powder (polymer (C-1)) (yield: 88%). The obtained polymer had an Mw of 9,300 and the dispersity index Mw/Mn of 1.60, and the ratio of the content of structural units derived from the compound (M-6), the compound (M-7), the compound (M-8), the compound (M-10) and the compound (M-9) in the polymer (C-1) was 16:26:19:28:11 (mol %). The content of fluorine atoms was 0% by mass.

TABLE 1

| | | Amount of compound blended (mol %) and | | | | | | | | | |
|---|---|---|---|---|---|---|---|---|---|---|---|
| | | content of each structural unit (mol %) | | | | | | | Physical | | Content of |
| | | Structural unit (I) | | | Structural unit (II) | | | | property | | fluorine |
| | (A) | | amount | | | amount | | Yield | value | | atoms (% |
| | Polymer | type | blended | content | type | blended | content | (%) | Mw | Mw/Mn | by mass) |
| Synthesis | A-1 | M-1/M-2 | 10/20 | 9.7/20.2 | M-3 | 70 | 70.1 | 82 | 9,400 | 1.50 | 27.9 |
| Example 1 | | | | | | | | | | | |
| Synthesis | A-2 | M-1/M-2 | 10/30 | 9.9/29.6 | M-3 | 60 | 60.5 | 81 | 9,600 | 1.49 | 26.5 |
| Example 2 | | | | | | | | | | | |
| Synthesis | A-3 | M-1/M-2 | 10/40 | 9.8/40.0 | M-3 | 50 | 50.2 | 73 | 9,500 | 1.49 | 25.1 |
| Example 3 | | | | | | | | | | | |
| Synthesis | A-4 | M-1/M-2 | 10/60 | 9.8/59.8 | M-3 | 30 | 30.4 | 83 | 9,400 | 1.50 | 22.0 |
| Example 4 | | | | | | | | | | | |
| Synthesis | A-5 | M-1/M-2 | 10/20 | 9.8/20.0 | M-4 | 70 | 70.2 | 71 | 11,600 | 1.51 | 15.6 |
| Example 5 | | | | | | | | | | | |
| Synthesis | A-6 | M-1/M-2 | 10/30 | 9.9/39.6 | M-4 | 60 | 50.5 | 52 | 11,300 | 1.50 | 15.8 |
| Example 6 | | | | | | | | | | | |
| Synthesis | A-7 | M-1/M-2 | 10/40 | 9.9/40.4 | M-4 | 50 | 49.7 | 60 | 11,500 | 1.51 | 15.9 |
| Example 7 | | | | | | | | | | | |
| Synthesis | A-8 | M-1/M-2 | 10/60 | 9.8/60.1 | M-4 | 30 | 30.1 | 65 | 11,400 | 1.50 | 16.1 |
| Example 8 | | | | | | | | | | | |
| Synthesis | A-9 | M-1/M-2 | 10/90 | 9.8/90.2 | — | — | — | 86 | 11,000 | 1.49 | 16.4 |
| Example 9 | | | | | | | | | | | |

### <Preparation of Photoresist Composition>

Details of each component used in preparation of Examples and Comparative Examples are shown below.

### [Acid Generating Agent]

D-1: a compound represented by the following formula

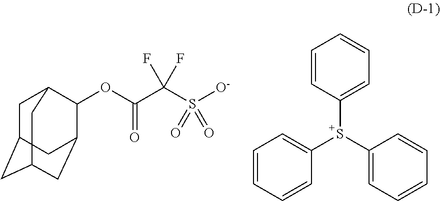

### [(E) Acid Diffusion Control Agent]

E-1: a compound represented by the following formula

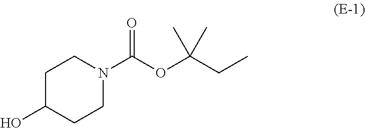

### Example 1

A solution was prepared by adding 5 parts by mass of the polymer (A-1) as the polymer (A), 5 parts by mass of the polymer (B-1) as the polymer (B), 100 parts by mass of the polymer (C-1) as the polymer (C), 10 parts by mass of the acid generating agent (D-1) as the acid generating agent (D), and 1.1 parts by mass of (E-1) as the diffusion control agent (E) to 1,850 parts by mass of propylene glycol monomethyl ether acetate, 790 parts by mass of cyclohexanone and 150 parts by mass of γ-butyrolactone as a solvent. This solution was filtered through a membrane filter having a pore size of 0.1 μm to prepare a photoresist composition.

### Examples 2 to 10 and Comparative Examples 1 to 6

Each photoresist composition was prepared by a similar operation to Example 1 except that the polymer (A), the polymer (B) and the polymer (C) of the type and the amount blended shown in Table 2 were used.

### <Evaluations>

Using each photoresist composition, the following characteristics were evaluated. The results of the evaluation are shown in Table 2 together.

### [Development Characteristic]

A resist film having a film thickness of 110 nm was formed with each photoresist composition on a silicon wafer having a diameter of 12 inches on which an underlayer antireflective film (ARC66, Nissan Chemical Industries, Ltd.) had been formed, and soft-baking (SB) was carried out at 120° C. for 50 sec. Next, this resist film was exposed through a line-and-space mask pattern (1 L/1 S) with a target size of a width of 45 nm using an ArF excimer laser Immersion Scanner (NIKON Corporation, NSR S610C) under a condition including NA of 1.3, ratio of 0.800, and Dipole. After the exposure, post-exposure baking (PEB) was carried out at 95° C. for 50 sec. Thereafter, the resist film was developed with a 2.38% by mass aqueous tetramethylammoniumhydroxide solution for 10 sec using a GP nozzle attached to a development apparatus of CLEAN TRACK ACT8 manufactured by Tokyo Electron Limited, followed by rinsing with pure water for 15 sec and spin drying at 2,000 rpm to form a positive type resist pattern. According to this procedure, an exposure dose at which a 1 L/1 S pattern having a line width of 45 nm was formed was determined to be an optimum exposure dose (sensitivity). A 1 L/1 S pattern having a line width of 45 nm was formed on the entire surface of the wafer with the optimal exposure dose, and the wafer was employed as a wafer for inspection of defects. It is to be noted that a scanning electron microscope (CC-4000, Hitachi High-Technologies Corporation) was used for the measurement of line-width. Thereafter, the number of defects on the wafer for inspection of defects was counted using KLA2810 (KLA-Tencor Corporation). Furthermore, the defects counted using KLA2810 (KLA-Tencor Corporation) were classified into the defects judged to be derived from the resist film, and those resulting from foreign substances derived from the outside. After the classification, with respect to a total number of defects judged to be derived from the resist film, the evaluation was made as: “favorable (A)” when the total number was less than 100/wafer; “somewhat favorable (B)” when the total number was 100/wafer to 500/wafer, and “unfavorable (C)” when the total number was greater than 500/wafer.

TABLE 2

| | (A) Polymer | | (B) Polymer | | (C) Base polymer | | | |
|---|---|---|---|---|---|---|---|---|
| | | parts by | | parts by | | parts by | Sensitivity | Development |
| | type | mass | type | mass | type | mass | (mJ) | defects |
| Example 1 | A-1 | 5 | B-1 | 5 | C-1 | 100 | 28.7 | A |
| Example 2 | A-2 | 5 | B-1 | 5 | C-1 | 100 | 27.6 | A |
| Example 3 | A-3 | 5 | B-1 | 5 | C-1 | 100 | 26.1 | A |
| Example 4 | A-4 | 5 | B-1 | 5 | C-1 | 100 | 25.5 | A |
| Example 5 | A-9 | 5 | B-1 | 5 | C-1 | 100 | 24.1 | A |
| Example 6 | A-5 | 5 | B-2 | 5 | C-1 | 100 | 28.5 | B |
| Example 7 | A-6 | 5 | B-2 | 5 | C-1 | 100 | 27.8 | A |
| Example 8 | A-7 | 5 | B-2 | 5 | C-1 | 100 | 26.8 | A |
| Example 9 | A-8 | 5 | B-2 | 5 | C-1 | 100 | 26.0 | A |
| Example 10 | A-9 | 5 | B-2 | 5 | C-1 | 100 | 23.7 | A |
| Comparative | — | — | B-1 | 5 | C-1 | 100 | 29.1 | C |
| Example 1 | | | | | | | | |
| Comparative | — | — | B-1 | 8 | C-1 | 100 | 28.9 | C |
| Example 2 | | | | | | | | |
| Comparative | — | — | B-1 | 10 | C-1 | 100 | 27.4 | C |
| Example 3 | | | | | | | | |
| Comparative | — | — | B-2 | 5 | C-1 | 100 | 29.2 | C |
| Example 4 | | | | | | | | |
| Comparative | — | — | B-2 | 8 | C-1 | 100 | 28.7 | C |
| Example 5 | | | | | | | | |
| Comparative | — | — | B-2 | 10 | C-1 | 100 | 27.5 | C |
| Example 6 | | | | | | | | |

From the results shown in Table 2, it was ascertained that generation of development defects was suppressed in Examples 1 to 10 as compared with Comparative Examples 1 to 6.

According to the photoresist composition of the embodiment of the present invention, a resist film can be formed while hydrophobicity can be secured during liquid immersion lithography, and an affinity with a developer solution increases in a development, whereby generation of development defects can be suppressed. Therefore, the photoresist composition can be suitably used for forming chemically amplified type resist films, particularly for forming a resist film for liquid immersion lithography, for producing semiconductor devices.

Obviously, numerous modifications and variations of the present invention are possible in light of the above teachings. It is therefore to be understood that within the scope of the appended claims, the invention may be practiced otherwise than as specifically described herein.

What is claimed is:

1. A photoresist composition comprising:
a first polymer having a fluorine atom and a first structural unit that includes a hydrophilic group;
a second polymer having a fluorine atom a second structural unit that includes an alkali-dissociable group; and
a third polymer having an acid-dissociable group,
the first polymer, the second polymer and the third polymer being different with one another.

2. The photoresist composition according to claim 1, wherein the first structural unit is represented by a following formula (1), and the second structural unit is is represented by a following formula (2): 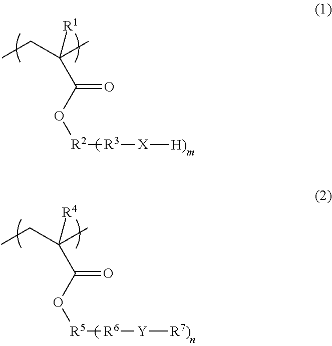
wherein, in the formula (1),
R¹ represents a hydrogen atom, a fluorine atom, a methyl group or a trifluoromethyl group;
R² represents a single bond or a hydrocarbon group having a valency of (m+1) and having 1 to 20 carbon atoms;
R³ represents a single bond, a bivalent hydrocarbon group having 1 to 20 carbon atoms or a bivalent heterocyclic group having 4 to 20 carbon atoms;
X represents a single bond, —CO—O—* or —O—, wherein * denotes a site bound to a hydrogen atom; and
m is an integer of 1 to 3, wherein in a case where m is or greater, a plurality of R³s and Xs are each a same or different, and a part or all of hydrogen atoms that the hydrocarbon group represented by R² and R³ has are unsubstituted or optionally substituted, and
wherein, in the formula (2),
R⁴ represents a hydrogen atom, a fluorine atom, a methyl group or a trifluoromethyl group;
R⁵ represents a hydrocarbon group having a valency of (n+1) and having 1 to 20 carbon atoms;
R⁶ represents a single bond, a bivalent hydrocarbon group having 1 to 20 carbon atoms or a bivalent heterocyclic group having 4 to 20 carbon atoms;
R⁷ represents a monovalent hydrocarbon group having 1 to 20 carbon atoms;
Y represents —CO—O—* or —O—CO—*, wherein “*” denotes a site bound to R⁷; and
n is an integer of 1 to 3, wherein in a case where n is 2 or greater, a plurality of R⁶s, R⁷s and Ys are each a same or different, and a part or all of hydrogen atoms that the hydrocarbon group represented by R⁵, R⁶ and R⁷ has are unsubstituted or optionally substituted.

3. The photoresist composition according to claim 1, wherein a mass ratio of the first polymer to the second polymer is no less than 0.2 and no greater than 2.0.

4. The photoresist composition according to claim 1, wherein a proportion of the third polymer contained with respect to a total of polymers is no less than 50% by mass.

5. The photoresist composition according to claim 1, wherein an amount of the first polymer with respect to 100 parts by mass of the third polymer is no less than 0.1 parts by mass and no greater than 10 parts by mass.

6. A method for forming a resist pattern, comprising:
providing the photoresist composition according to claim 1 on a substrate to form a resist film;
exposing the resist film with liquid immersion lithography; and
developing the exposed resist film.

7. A method for producing a photoresist composition, comprising: mixing
a first polymer having a fluorine atom and a first structural unit that includes a hydrophilic group,
a second polymer having a fluorine atom and a second structural unit that includes an alkali-dissociable group, and
a third polymer having an acid-dissociable group.

8. The method according to claim 7, wherein the first structural unit is represented by a following formula (1), and the second structural unit (II) is represented by a following formula (2): 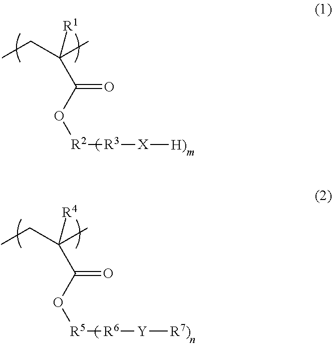
wherein, in the formula (1),
R¹ represents a hydrogen atom, a fluorine atom, a methyl group or a trifluoromethyl group;
R² represents a single bond or a hydrocarbon group having a valency of (m+1) and having 1 to 20 carbon atoms;
R³ represents a single bond, a bivalent hydrocarbon group having 1 to 20 carbon atoms or a bivalent heterocyclic group having 4 to 20 carbon atoms;
X represents a single bond, —CO—O—* or —O—, wherein “*” denotes a site bound to a hydrogen atom; and
m is an integer of 1 to 3, wherein in a case where m is or greater, a plurality of R³s and Xs are each a same or different, and a part or all of hydrogen atoms that the hydrocarbon group represented by R² and R³ has are unsubstituted or optionally substituted, and
wherein, in the formula (2),
R⁴ represents a hydrogen atom, a fluorine atom, a methyl group or a trifluoromethyl group;
R⁵ represents a hydrocarbon group having a valency of (n+1) and having 1 to 20 carbon atoms;
R⁶ represents a single bond, a bivalent hydrocarbon group having 1 to 20 carbon atoms or a bivalent heterocyclic group having 4 to 20 carbon atoms;
R⁷ represents a monovalent hydrocarbon group having 1 to 20 carbon atoms;
Y represents —CO—O—* or —O—CO—*, wherein “*” denotes a site bound to R⁷; and
n is an integer of 1 to 3, wherein in a case where n is 2 or greater, a plurality of R⁶s, R⁷s and Ys are each a same or different, and a part or all of hydrogen atoms that the hydrocarbon group represented by R⁵, R⁶ and R⁷ has are unsubstituted or optionally substituted.

9. The method according to claim 7, wherein a mass ratio of the first polymer to the second polymer is no less than 0.2 and no greater than 2.0.

10. The method according to claim 7, wherein a proportion of the third polymer contained with respect to a total of the first, second and third polymers is no less than 50% by mass.

11. The method according to claim 7, wherein an amount of the first polymer with respect to 100 parts by mass of the third polymer is no less than 0.1 parts by mass and no greater than 10 parts by mass.
